(19) United States
(12) Patent Application Publication
(10) Pub. No.: US 2025/0093594 A1
(43) Pub. Date: Mar. 20, 2025

(54) SEMICONDUCTOR PACKAGE INCLUDING PHOTONIC INTEGRATED CIRCUIT CHIP

(71) Applicant: Samsung Electronics Co., Ltd., Suwon-si (KR)

(72) Inventors: Junghoon Kang, Suwon-si (KR); Daegon Kim, Suwon-si (KR)

(21) Appl. No.: 18/747,906

(22) Filed: Jun. 19, 2024

(30) Foreign Application Priority Data
Sep. 15, 2023 (KR) 10-2023-0123326

(51) Int. Cl. G02B 6/42; H01L 23/00; H01L 23/13; H01L 23/48; H01L 23/498; H01L 23/538; H01L 25/16; H01L 27/144

(52) U.S. Cl. CPC G02B 6/4231; G02B 6/4243; H01L 23/13; H01L 23/481; H01L 23/5383; H01L 25/167; H10F 39/10; H01L 23/49816; H01L 24/08; H01L 24/16; H01L 2224/08225; H01L 2224/16145; H01L 2224/16227

(57) ABSTRACT

A semiconductor package includes a package substrate including an alignment hole extending inwardly from a side surface of the package substrate, a photonic integrated circuit chip disposed on the package substrate, the of the package substrate chip including a groove extending inwardly from a side surface of the PIC chip and a photo-electron conversion unit including an edge coupler, and an optical fiber connector including a frame, an optical fiber mounted in the groove of the of the package substrate chip and passing through the frame, and an alignment pin extending from the frame to an inside of the alignment hole, wherein the edge coupler is located at one end of the photo-electron conversion unit.

### CROSS-REFERENCE TO RELATED APPLICATION

This application is based on and claims priority under 35 USC § 119 to Korean Patent Application No. 10-2023-0123326, filed on Sep. 15, 2023, in the Korean Intellectual Property Office, the disclosure of which is incorporated by reference herein in its entirety.

### BACKGROUND

Aspects of the inventive concept relate to a semiconductor package and a method of manufacturing the same, and more particularly, to a semiconductor package including a photonic integrated circuit chip and a method of manufacturing the same.

The advantages of semiconductor packages have been increasingly utilized to improve the functionality of electronic devices and integrate components. Semiconductor packages allow various integrated circuits, such as memory chips or logic chips, to be mounted on a package substrate thereof. With the recent increase in data traffic in data centers and telecommunications infrastructures, research into semiconductor packages containing photonic integrated circuits has been ongoing.

### SUMMARY

Aspects of the inventive concept provide a semiconductor package having a wide bandwidth.

Aspects of the inventive concept also provide a semiconductor package with a reduced alignment error in the vertical direction.

In addition, the invention is not limited to the examples given in this specification, and other embodiments may encompass the invention as understood by those skilled in the art from the description below.

According to an aspect of the inventive concept, a semiconductor package includes a package substrate including an alignment hole extending inwardly from a side surface of the package substrate, a photonic integrated circuit (PIC) chip disposed on the package substrate, the PIC chip including a groove extending inwardly from a side surface of the PIC chip and a photo-electron conversion unit including an edge coupler, and an optical fiber connector including a frame, an optical fiber mounted in the groove of the PIC chip and passing through the frame, and an alignment pin extending from the frame to an inside of the alignment hole, wherein the edge coupler is located at one end of the photo-electron conversion unit.

According to another aspect of the inventive concept, a semiconductor package includes a package substrate including at least a first alignment hole extending inwardly from a side surface of the package substrate, a photonic integrated circuit (PIC) chip disposed on the package substrate, the PIC chip including a groove extending inwardly from a side surface of the PIC chip and a photo-electron converter including a plurality of terminal end couplers, a semiconductor chip disposed on the package substrate, and an optical fiber connector including a frame, a plurality of optical fibers penetrating through the frame, and at least a first alignment pin extending from the frame to an inside of the first alignment hole, wherein the plurality of terminal end couplers are located at a first end of the photo-electron converter.

According to another aspect of the inventive concept, a semiconductor package includes a package substrate including at least a first alignment hole extending inwardly from a side surface of the package substrate, a photonic integrated circuit (PIC) chip disposed on the package substrate, the PIC chip including a groove extending inwardly from a side surface of the PIC chip and a photo-electron converter including a plurality of terminal couplers, a semiconductor chip disposed on the package substrate, an electronic integrated circuit (EIC) chip disposed on an upper surface of the PIC chip, and an optical fiber unit including a frame, a plurality of optical fibers penetrating through the frame and mounted in the groove, and at least a first alignment pin extending from the frame into an inside of the first alignment hole, wherein the plurality of terminal end couplers are located at one end of the photo-electron converter, and the first alignment hole of the package substrate is apart from upper and lower surfaces of the package substrate.

### BRIEF DESCRIPTION OF THE DRAWINGS

Embodiments will be more clearly understood from the following detailed description taken in conjunction with the accompanying drawings in which:

FIG. 1 is a perspective view schematically illustrating a semiconductor package according to an embodiment;

FIG. 2 is a plan view schematically illustrating the semiconductor package of FIG. 1;

FIG. 3 is a schematic cross-sectional view of the semiconductor package of FIG. 1 cut along line A-A′ of FIG. 2;

FIG. 4 is a schematic cross-sectional view of the semiconductor package of FIG. 1 cut along line B-B′ of FIG. 2;

FIG. 5 is a schematic cross-sectional view of the semiconductor package of FIG. 1 in which portion “EX” of FIG. 4 is enlarged;

FIG. 6 is a schematic cross-sectional view of the semiconductor package cut along line B-B′ of FIG. 2, according to an embodiment;

FIG. 7 is a schematic cross-sectional view of the semiconductor package cut along line B-B′ of FIG. 2, according to an embodiment;

FIG. 8 is a schematic cross-sectional view of the semiconductor package according to an embodiment, in which the portion “EX” of FIG. 4 is enlarged;

FIG. 9 is a schematic cross-sectional view of the semiconductor package cut along line A-A′ of FIG. 2, according to an embodiment;

FIG. 10 is a schematic cross-sectional view of a semiconductor package cut along line A-A′ of FIG. 2, according to an embodiment; and

FIG. 11 is a schematic cross-sectional view of a semiconductor package cut along line A-A′ of FIG. 2, according to an embodiment.

### DETAILED DESCRIPTION OF THE EMBODIMENTS

These embodiments may be subject to various changes and have various forms, and thus, some embodiments are illustrated in the drawings and described in detail. However, this is not intended to limit the present embodiments to the specific disclosure form.

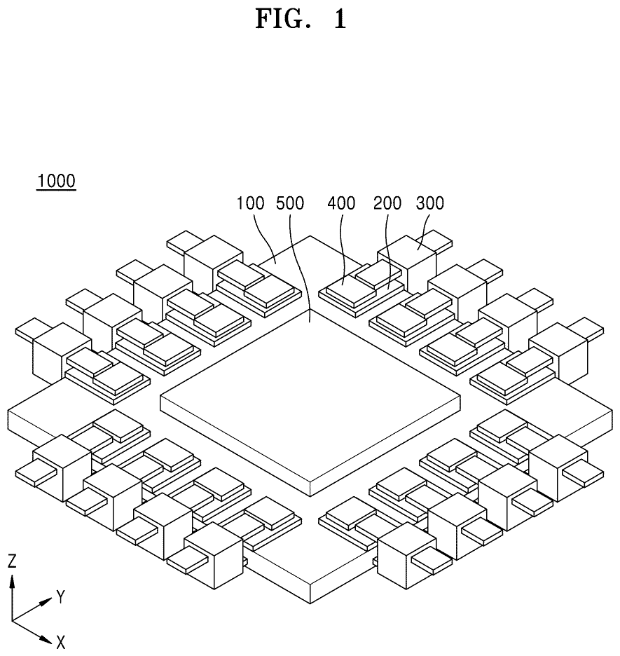

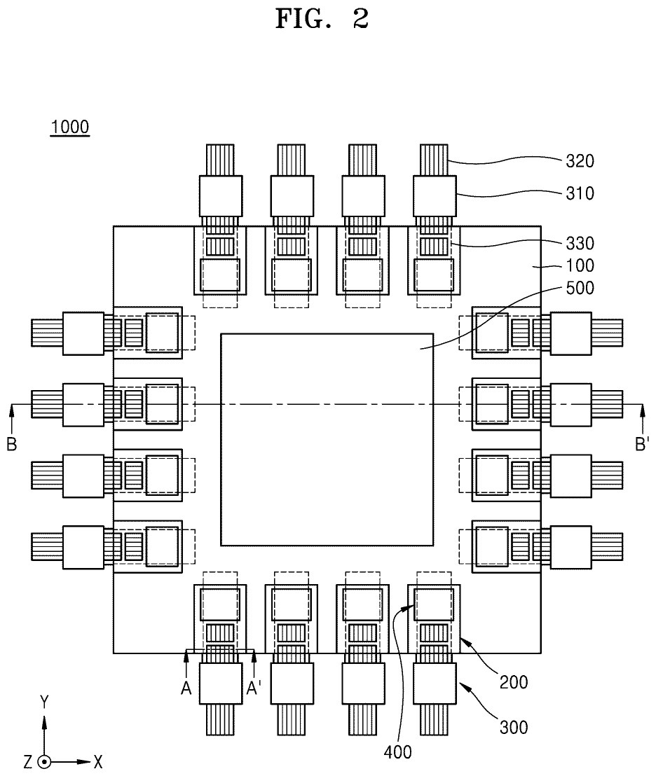

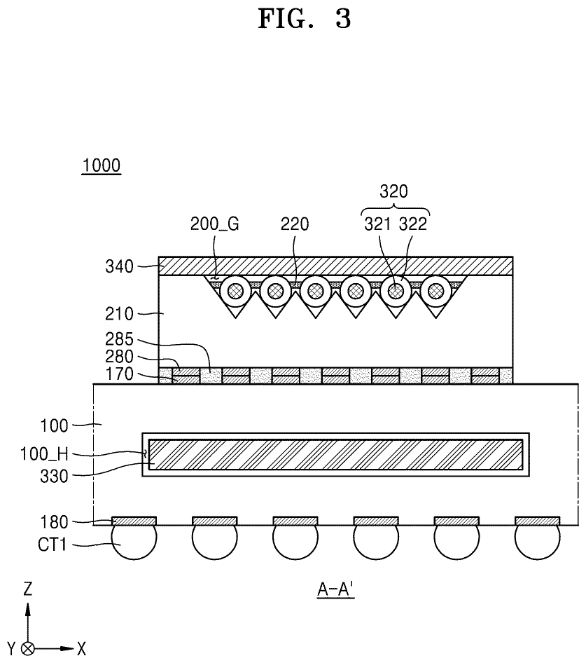

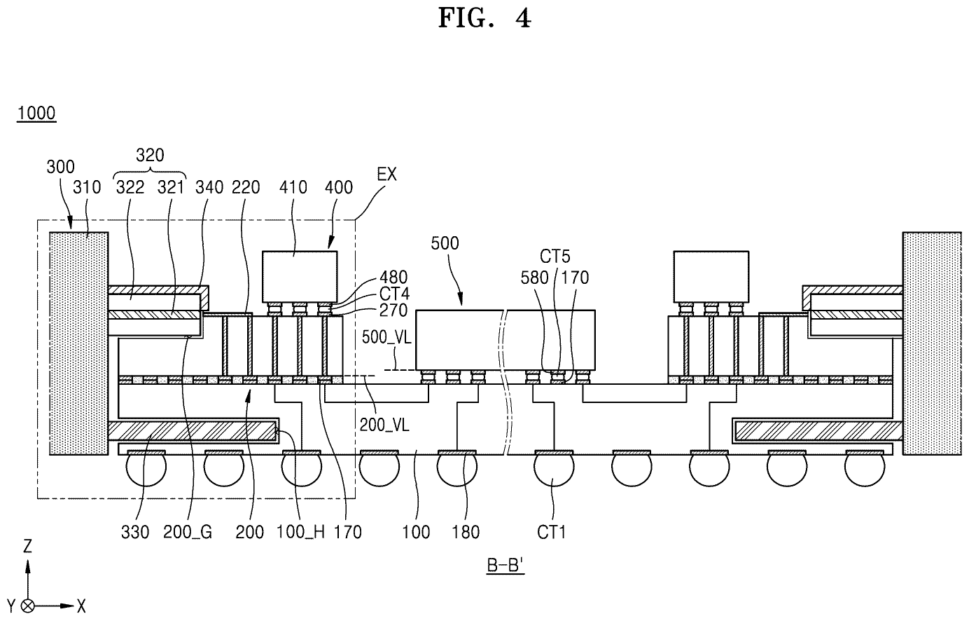

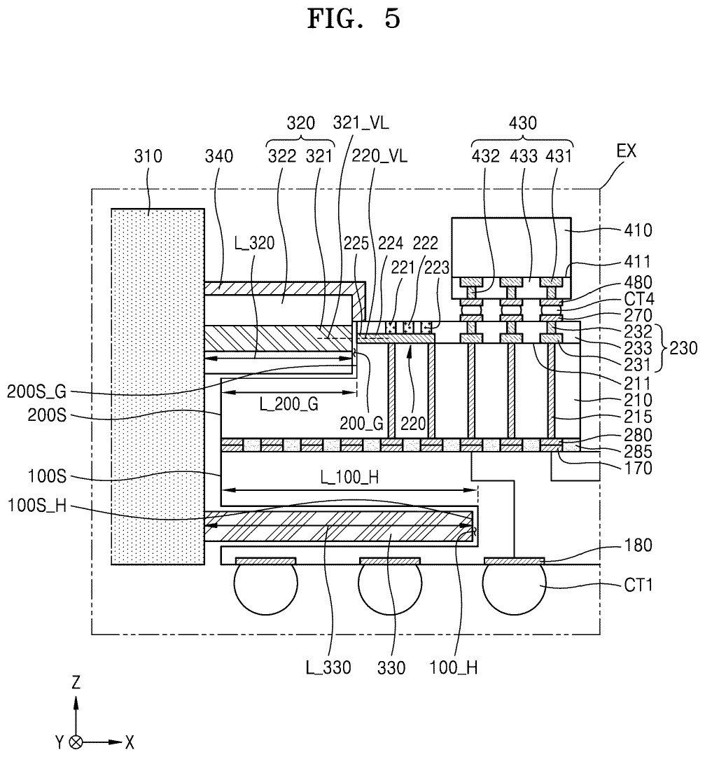

FIG. 1 is a perspective view schematically illustrating a semiconductor package 1000 according to an embodiment. FIG. 2 is a plan view schematically illustrating the semiconductor package 1000 of FIG. 1. FIG. 3 is a schematic cross-sectional of the semiconductor package 1000 of FIG. 1 cut along line A-A′ of FIG. 2. FIG. 4 is a schematic cross-sectional view of the semiconductor package 1000 of FIG. 1 cut along line B-B′ of FIG. 2. FIG. 5 is a schematic cross-sectional view of the semiconductor package 1000 of FIG. 1 in which a portion “EX” of FIG. 4 is enlarged.

Referring to FIGS. 1 to 5, the semiconductor package 1000 may include a package substrate 100, a photonic integrated circuit (PIC) chip 200, an electronic integrated circuit (EIC) chip 400, a semiconductor chip 500, and an optical fiber unit 300.

Hereinafter, unless specifically defined, a direction parallel to an upper surface of the package substrate 100 is defined as a first direction (an X direction), a direction perpendicular to the upper surface of the package substrate 100 is defined as a vertical direction (a Z direction), and a direction perpendicular to the first direction (the X direction) and the vertical direction (the Z direction) is defined as a second direction (a Y direction). The first direction (the X direction) and the second direction (the Y direction) may be horizontal directions and may define a plane that extends horizontally.

The package substrate 100 of the semiconductor package 1000 may be, for example, a printed circuit board (PCB). The package substrate 100 may include a core insulating layer including or formed of at least one material selected from a phenol resin, an epoxy resin, and polyimide. For example, the core insulating layer may include or be formed of at least one material selected from polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The package substrate 100 may include an upper pad 170 located at or on an upper surface of the core insulating layer and a lower pad 180 located at or on a lower surface of the core insulating layer. The upper pad 170 and lower pad 180 may be portions of a circuit interconnection patterned after the upper and lower surfaces of the core insulating layer is coated with copper foil (Cu foil). In detail, the upper pad 170 and the lower pad 180 may be regions of the circuit interconnection that are not covered by a solder resist layer and are exposed externally. Though a single upper pad 170 and lower pad 180 may be described herein, as shown in FIGS. 3 and 4, a plurality of upper pads 170 and plurality of lower pads 180 may be formed. Various elements described herein in the singular may be provided in plural, as can be seen in the figures or from the context in which they are described.

In some embodiments, the upper pad 170 and lower pad 180 may each include or be formed of copper, nickel, stainless steel, or beryllium copper. An internal interconnection, also described as an internal interconnection line, may be formed within the package substrate 100 to electrically connect the upper pad 170 to the lower pad 180.

External connection terminals CT1 may be attached to the lower pads 180. The external connection terminals CT1 may be configured to electrically and physically connect the package substrate 100 and an external device on which the package substrate 100 is mounted. The external connection terminals CT1 may be formed from, for example, solder balls or solder bumps.

An alignment hole 100_H of the package substrate 100 may extend inwardly from a side surface 100S of the package substrate 100. The alignment hole 100_H may be apart from the upper and lower surfaces of the package substrate 100. For example, the alignment hole 100_H may be a space with a ceiling and bottom.

In some embodiments, a shape of the alignment hole 100_H may correspond to a shape of an alignment pin 330 of the optical fiber unit 300. For example, a cross-section of the alignment hole 100_H taken in a direction perpendicular to an extension direction of the alignment hole 100_H may be the same as a cross-section of the alignment pin 330 taken in a direction perpendicular to an extension direction of the alignment pin 330. The extension direction of the alignment hole 100_H may be parallel to the extension direction of the alignment pin 330. The alignment pin 330 may fit securely into the alignment hole 100_H.

The PIC chip 200 of the semiconductor package 1000 may be located on the package substrate 100. In some embodiments, the PIC chip 200 may be located at an edge region of the upper surface of the package substrate 100, and the semiconductor chip 500 may be located at the center region of the upper surface of the package substrate 100.

In some embodiments, the semiconductor package 1000 may include a plurality of PIC chips 200, and the PIC chips 200 may be arranged in a row along each side of the upper surface of the package substrate 100. In FIG. 2, four PIC chips 200 are shown to be arranged on each side of the upper surface of the package substrate 100, but the number of the PIC chips 200 is not limited thereto. The PIC chips 200 may be positioned at least partly at the same vertical level above the package substrate 100 as the semiconductor chip 500.

Each PIC chip 200 of the semiconductor package 1000 may input and output optical signals. In detail, each PIC chip 200 may convert an electrical signal into an optical signal and transmit the optical signal to the optical fiber 320, and convert an optical signal transmitted from the optical fiber 320 into an electrical signal and transmit the electrical signal to the EIC chip 400.

The PIC chip 200 may include a first substrate 210, a first interconnection structure 230, a photo-electron conversion unit 220, and a first through-via 215. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The first substrate 210 may include or be formed from a semiconductor material, such as silicon (Si). Alternatively, the first substrate 210 may include or be formed from a semiconductor material, such as germanium (Ge).

The first substrate 210 may include an active surface 211 on which a plurality of individual devices are formed and an inactive surface opposite to the active surface 211. The first interconnection structure 230 may be formed on the active surface 211 of the first substrate 210. The first through-via 215 may extend from the inactive surface of the first substrate 210 to the active surface 211. In some embodiments, the first through-via 215 may be electrically connected to a plurality of individual devices on the first interconnection structure 230 and/or the active surface 211.

The PIC chip 200 may be disposed on the package substrate 100 so that the active surface 211 of the first substrate 210 of the PIC chip 200 faces the EIC chip 400. For example, the PIC chip 200 may be disposed on the package substrate 100 in a face-up manner. In this specification, the active surface 211 of the first substrate 210 may be referred to as an upper surface of the first substrate 210, and the inactive surface of the first substrate 210 may be referred to as a lower surface of the first substrate 210. However, a vertical relationship between the active surface 211 and the inactive surface is not limited thereto. Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

A groove 200_G of the PIC chip 200 may extend inwardly from a side surface 200S and an upper surface of the PIC chip 200. For example, the groove 200_G may contact, or be formed at, the upper and side surfaces 200S of the PIC chip 200. For example, the groove 200_G may be adjacent one side of the upper surface of the PIC chip 200. For example, the groove 200_G may be a region in which the first substrate 210 is absent, so the inside of the first substrate 210 may be exposed. Accordingly, as viewed from a particular direction, the optical fiber 320 may have a vertical length greater than a depth of the groove 200_G in the vertical direction (the Z direction).

In some embodiments, the groove 200_G may be referred to as a V-groove. The groove 200_G may also be generally referred to as a recess. A cross-section of the groove 200_G, taken in a direction perpendicular to a direction in which the groove 200_G extends, may have a shape in which V-shaped grooves are arranged along the side 200S of the PIC chip 200 in a partially overlapping manner. For example, the optical fiber 320 may be mounted in each of the V-shaped grooves. Therefore, one overall groove 200_G in the first substrate 210 may include a plurality of sub-grooves, or smaller grooves, each of which is V-shaped, and each of which is adjacent to at least one other sub-groove.

In some embodiments, an extension length L_200_G (e.g. horizontal extension length in the Y direction) of the groove 200_G may be different from an extension length L_100_H (e.g. horizontal extension length in the Y direction) of the alignment hole 100_H. In some embodiments, the extension length L_200_G of the groove 200_G may be shorter than the extension length L_100_H of the alignment hole 100_H.

In some embodiments, a side surface 200S_G of the PIC chip 200 forming a sidewall of the groove 200_G may be closer to a frame 310 of the optical fiber unit 300 than a side surface 100S_H of the package substrate 100 forming a sidewall of the alignment hole 100_H. The sidewall 200S_G, among sidewalls of the groove 200_G, farthest from the frame 310 of the optical fiber unit 300 may be closer to the frame 310 of the optical fiber unit 300 than the sidewall 100S_H, among sidewalls of the alignment hole 100_H, farthest from the frame 310 of the optical fiber unit 300.

In some embodiments, the side surface in which the groove 200_G is located, in the side surface 200S of the PIC chip 200, and the side surface in which the alignment hole 100_H is located, in the side surface 100S of the package substrate 100, may face the frame 310 of the optical fiber unit 300. For example, the side surface in which the groove 200_G is located, in the side surface 200S of the PIC chip 200, may face the same direction as the side surface in which the alignment hole 100_H is located, in the side surface 100S of the package substrate 100.

In some embodiments, the side surface 200S of the PIC chip 200 in which the groove 200_G is located may be coplanar with the side surface 100S of the package substrate 100 in which the alignment hole 100_H is located. A horizontal distance between the frame 310 and the package substrate 100 may be equal to a distance between the frame 310 and the PIC chip 200.

The photo-electron conversion unit 220 of the PIC chip 200 may convert optical signals into electrical signals and electrical signals into optical signals. In some embodiments, the photo-electron conversion unit 220 may include a photodetector 221, a laser diode 222, a modulator 223, a waveguide 224, and an edge coupler 225.

In the process of inputting an optical signal to the PIC chip 200, the photodetector 221 may detect the optical signal input to the PIC chip 200. An optical signal may be detected through the photodetector 221 and converted into an electrical signal. The electrical signal converted by the photodetector 221 may be transmitted to the individual devices on the active surface 211 of the first substrate 210 of the PIC chip 200.

In the process of the PIC chip 200 outputting an optical signal, the individual devices on the active surface 211 of the first substrate 210 of the PIC chip 200 may transmit electrical signals to the modulator 223. According to an electrical signal, the modulator 223 may input the signal to light emitted by the laser diode 222 to convert light into an optical signal.

The waveguide 224 may be a path along which an optical signal moves in the PIC chip 200. The waveguide 224 may be a path through which the optical signal transmitted to the edge coupler 225 moves to the photodetector 221 or may be a path through which the optical signal converted by the modulator 223 moves to the edge coupler 225. For example, the optical signal may move along the waveguide 224 in a horizontal direction on the upper surface of the PIC chip 200.

The edge coupler 225 may be a portion of the waveguide 224. For example, the edge coupler 225 may be a region of the waveguide 224 on which an optical signal emitted from the optical fiber 320 is incident. The edge coupler 225 may be a region in which the optical signal from the waveguide 224 is emitted to the optical fiber 320. The edge coupler 225 may be a terminal end of the waveguide 224, and may be referred to as a terminal end coupler.

In some embodiments, the edge coupler 225 may have a different horizontal width from those of other regions of the waveguide 224. That is, the edge coupler 225 may have a different horizontal width from those of other regions of the waveguide 224 to ensure accuracy in transmitting/receiving optical signals. For example, the horizontal width of the edge coupler 225 may decrease toward the optical fiber 320.

In some embodiments, the waveguide 224 may be located such that the edge coupler 225 faces the groove 200_G. Accordingly, the edge coupler 225 may face the optical fiber 320.

In some embodiments, the photo-electron conversion unit 220 may include a plurality of edge couplers 225. The edge couplers 225 may correspond to a plurality of optical fibers 320, respectively. The optical fibers 320 may face different edge couplers 225. That is, each of the optical fibers 320 may input/output an optical signal to a corresponding one edge coupler 225 among the edge couplers 225. As shown in FIG. 3, when the optical fiber unit 300 includes six optical fibers 320, the photo-electron conversion unit 220 may include six edge couplers 225.

In some embodiments, the edge coupler 225 may have a constant length, i.e., a thickness, in the vertical direction (the Z direction). In other words, unlike a grating coupler, the edge coupler 225 may not have a region in which the thickness varies. For example, the thickness of the edge coupler 225 may be the same as a thickness of other regions of the waveguide 224. Here, the thickness may refer to a maximum thickness in the vertical direction (e.g., at a middle portion of the edge coupler 225 when viewed from the Y direction).

In FIG. 4, although the photo-electron conversion unit 220 is shown to be buried in the first insulating layer 233, the photo-electron conversion unit 220 (also described as a photo-electron converter, or a light-to-electrical conversion unit or converter) is not limited thereto and may be covered by an oxide layer distinguished from the first insulating layer 233. That is, an oxide layer may be formed on one side of the first insulating layer 233, and the photo-electron conversion unit 220 may be located inside the oxide layer.

The first interconnection structure 230 of the PIC chip 200 may include a plurality of first interconnection patterns 231, a plurality of first interconnection vias 232 connected to the first interconnection patterns 231, and a first insulating layer 233 surrounding the first interconnection patterns 231 and the first interconnection vias 232. In some embodiments, the first interconnection structure 230 may have a multi-layer interconnection structure including the first interconnection patterns 231 and the first interconnection vias 232 at different vertical levels. The first interconnection patterns 231 and first interconnection vias 232 may include or be formed of a conductive material, such as a metal.

In some embodiments, the PIC chip 200 may further include a lower pad 280. The lower pad 280 may be disposed on a lower surface of the PIC chip 200 and electrically connected to the first through-via 215.

In some embodiments, the lower pad 280 of the PIC chip 200 may be electrically connected to an upper pad 170 of the package substrate 100 through a non-conductive film 285. However, the PIC chip 200 may be electrically connected to the package substrate 100 by a non-conductive film or direct coupling.

A vertical level 200_VL of the lower surface of the PIC chip 200 may be lower than a vertical level 500_VL of the lower surface of the semiconductor chip 500. The lower pad 280 of the PIC chip 200 may contact the upper pad 170 of the package substrate 100, and a lower pad 580 of the semiconductor chip 500 may be apart from the upper pad 170 of the package substrate 100 with a connection terminal CT5 therebetween. The term “contact,” “contacting,” “contacts,” or “in contact with,” as used herein, refers to a direct connection (i.e., touching) unless the context clearly indicates otherwise. Accordingly, the vertical level 200_VL of the lower surface of the PIC chip 200 may be lower than the vertical level 500_VL of the lower surface of the semiconductor chip 500 by a length of the connection terminal CT5 in the vertical direction (the Z direction). For example, the vertical a distance from the lower surface of the package substrate 100 in the vertical direction (the Z direction) to the lower surface of the PIC chip 200 may be less than the distance from the lower surface of the package substrate 100 in the vertical direction to the lower surface of the semiconductor chip 500.

In some embodiments, the PIC chip 200 may further include an upper pad 270. The upper pad 270 may be disposed on an upper surface of the first interconnection structure 230 of the PIC chip 200 and may be electrically connected to the first interconnection patterns 231 and/or the first interconnection vias 232.

The EIC chip 400 of the semiconductor package 1000 may be disposed on the PIC chip 200. The EIC chip 400 may be apart from the package substrate 100 with the PIC chip 200 therebetween.

The EIC chip 400 may include a second substrate 410 and a second interconnection structure 430. The second substrate 410 of the EIC chip 400 may include an active surface 411 and an inactive surface opposite to the active surface 411. The second interconnection structure 430 may be formed on the active surface of the second substrate 410.

In some embodiments, the EIC chip 400 may be disposed on the PIC chip 200 such that the active surface 411 of the second substrate 410 faces the PIC chip 200. For example, the EIC chip 400 may be located on the PIC chip 200 in a face-down manner.

The second substrate 410 may include or be formed from a semiconductor material, such as silicon (Si). Alternatively, the second substrate 410 may include or be formed from a semiconductor material, such as germanium (Ge).

In some embodiments, the EIC chip 400 may include a plurality of individual devices that the PIC chip 200 uses to interface with other individual devices. The individual devices of the EIC chip 400 may be located on the active surface 411 of the second substrate 410. For example, the EIC chip 400 may include CMOS drivers, transimpedance amplifiers, etc. to perform functions, such as controlling high-frequency signaling of the PIC chip 200, etc.

The second interconnection structure 430 of the EIC chip 400 may include a plurality of second interconnection patterns 431, a plurality of second interconnection vias 432 respectively connected to the second interconnection patterns 431, and a second insulating layer 433 covering the second interconnection patterns 431 and the second interconnection vias 432. In some embodiments, the second interconnection structure 430 may have a multi-layer interconnection structure including the second interconnection patterns 431 and the second interconnection vias 432 at different vertical levels.

In some embodiments, the EIC chip 400 may further include a lower pad 480. The lower pad 480 may be disposed on a lower surface of the EIC chip 400 and may be electrically connected to the second interconnection pattern 431 and/or the second interconnection via 432.

In some embodiments, the lower pad 480 of the EIC chip 400 may be electrically connected to the upper pad 270 of the PIC chip 200 through the connection terminal CT4. However, a connection method of the EIC chip 400 and the PIC chip 200 is not limited thereto.

The semiconductor chip 500 of the semiconductor package 1000 may be located on the package substrate 100. In some embodiments, the semiconductor chip 500 may be apart from (e.g., horizontally spaced apart from) the PIC chip 200 and located in the center of the package substrate 100.

The semiconductor chip 500 may include an active surface and an inactive surface opposite to the active surface. In some embodiments, the semiconductor chip 500 may include an application specific integrated circuit (ASIC).

In some embodiments, the semiconductor chip 500 may be mounted on the package substrate 100 with the active surface facing down. In some embodiments, the lower pad 580 of the semiconductor chip 500 may be electrically connected to the upper pad 170 of the package substrate 100 through the connection terminal CT5. However, a connection method of the semiconductor chip 500 and the package substrate 100 is not limited thereto. In some embodiments, each of the connection terminal CT4 and the connection terminal CT5 may be, for example, a conductive bump, such as a solder bump.

In some embodiments, a plurality of various types of individual devices may be located on the active surface of the semiconductor chip 500. For example, the individual devices may include various microelectronic devices, for example, a complementary metal-oxide semiconductor (CMOS) transistor, a metal-oxide-semiconductor filed effect transistor (MOSFET), a system large scale integration (LSI), an image sensor, such as a CMOS imaging sensor (CIS), a micro-electro-mechanical system (MEMS), an active device, a passive device, etc.

The optical fiber unit 300 of the semiconductor package 1000 may include a frame 310, at least one optical fiber 320, and at least one alignment pin 330. The frame 310 of the optical fiber unit 300 may be located outside the package substrate 100. For example, the frame 310 may be apart from a side surface of the package substrate 100 in the horizontal direction. The optical fiber unit 300 may be described as an optical fiber connector, an optical input/output connector or an optical input/output plug.

In some embodiments, the optical fiber 320 and the alignment pin 330 may extend from one side surface of the frame 310 toward the PIC chip 200 and the package substrate 100. One side surface of the frame 310 may face the groove 200_G of the PIC chip 200 and the alignment hole 100_H of the package substrate 100. That is, one side surface of the frame 310 may face the side surface in which the groove 200_G is located, in the side surface 200S of the PIC chip 200, and may face the side surface in which the alignment hole 100_H is located, in the side surface 100S of the package substrate 100. The frame 310 maybe formed of a material such as a stainless steel, and a plastic material, and may have a block shape that surrounds and encases a portion of the optical fibers 320 and a portion of the alignment pin 330.

The optical fiber 320 may pass through the frame 310 and be mounted inside the groove 200_G of the PIC chip 200. In detail, the optical fiber 320 may be fixed inside the groove 200_G by a clamping lead 340 located above the optical fiber 320. For example, the clamping lead 340 may be the ceiling of the groove 200_G, such that the groove 200_G is defined by a recess in the first substrate 210 which is covered by the clamping lead 340. In some embodiments, an empty space between the optical fiber 320 and the groove 200_G may be filled with a transparent epoxy material.

The optical fiber 320 may include a core layer 321 and a clad layer 322 covering the core layer 321. The core layer 321 may have a relatively high refractive index, and the clad layer 322 may have a relatively low refractive index. An optical signal incident on the core layer 321 may move along the core layer 321 having a high refractive index. The optical signal traveling from the core layer 321 to the clad layer 322 may be totally reflected and move along the core layer 321 due to a difference in refractive index between the core layer 321 and the clad layer 322.

In some embodiments, the optical fiber unit 300 may include a plurality of optical fibers 320. The optical fibers 320 may input/output optical signals having different wavelengths. The optical fibers 320 may emit optical signals to different edge couplers 225. The optical fibers 320 may emit optical signals to the edge couplers 225 having substantially the same cross-sectional shape.

In some embodiments, each optical fiber 320 may input/output optical signals having multiple wavelengths. For example, the optical signal emitted by each optical fiber 320 may have multiple peak wavelengths. Here, one optical fiber 320 may emit optical signals having multiple wavelengths to one edge coupler 225.

The optical fibers 320 of the semiconductor package 1000 may emit optical signals having multiple wavelengths, and the photo-electron conversion unit 220 of the PIC chip 200 may transmit/receive the optical signals having multiple wavelengths. Accordingly, the semiconductor package 1000 may have a relatively wide bandwidth.

At one end of the optical fiber 320 facing the edge coupler 225, a vertical level 321_VL of the core layer 321 of the optical fiber 320 may be substantially equal to a vertical level 220_VL of the edge coupler 225. For example, the optical fiber 320 may be mounted in the groove 200_G so that the center of the core layer 321 is aligned with the center of the edge coupler 225 in the vertical direction. In some embodiments, at one end of the optical fiber 320 facing the edge coupler 225, the vertical level 321_VL of the core layer 321 of the optical fiber 320 may differ by less than 1 mm from the vertical level 220_VL of the edge coupler 225. For example, in the process of mounting the optical fiber 320 on the PIC chip 200, an error in the vertical direction (the Z direction) may be reduced to less than 1 mm. Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes

The alignment pin 330 may extend from the frame 310 to the inside of the alignment hole 100_H of the package substrate 100. The alignment pin 330 may be inserted into the alignment hole 100_H of the package substrate 100. In some embodiments, an empty space between the alignment hole 100_H and the alignment pin 330 may be filled with an epoxy material.

According to some descriptions herein, a first side surface of the frame 310 refers to a side surface that is in contact with the alignment pin 330 and the optical fiber 320, in the side surface of the frame 310 (e.g., a side surface of the frame 310 from which the alignment pin 330 and the optical fiber 320 extend). For example, the groove 200_G and the alignment hole 100_H may face the first side surface of the frame 310. A first length L_320 refers to a length from the first side surface of the frame 310 to the end of the optical fiber 320 located within the groove 200_G, and a second length L_330 refers to a length from the first side surface of the frame 310 to the end of the alignment pin 330 located in the alignment hole 100_H.

In some embodiments, the first length L_320 may be different from the second length L_330. For example, the first length L_320 may be less than the second length L_330. A length of the optical fiber 320 extending from the first side surface of the frame 310 into the groove 200_G may be shorter than a length of the alignment pin 330 extending from the first side surface of the frame 310 into the alignment hole 100_H.

In the process of connecting the optical fiber unit 300 to the PIC chip 200, as the alignment pin 330 of the optical fiber unit 300 is pre-aligned in the alignment hole 100_H, the optical fibers 320 may be automatically aligned with the edge couplers 225.

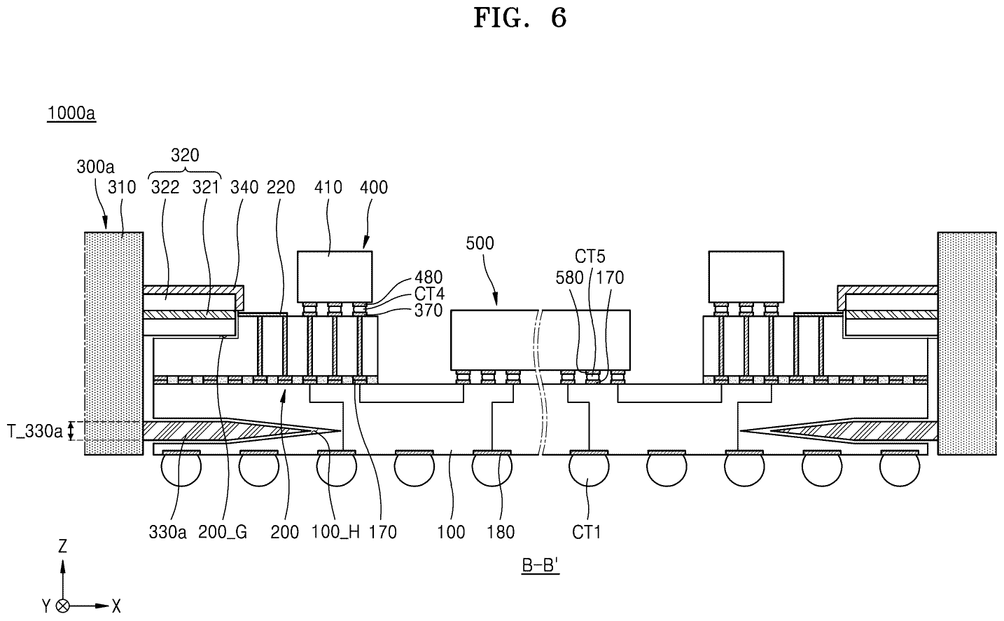

FIG. 6 is a cross-sectional view schematically illustrating a semiconductor package 1000a, taken along line B-B′ of FIG. 2, according to an embodiment.

Most of the components constituting the semiconductor package 1000a described below and materials forming the components are substantially the same as or similar to those described above with reference to FIG. 1. Therefore, for convenience of explanation, the description focuses on differences between the semiconductor package 1000a of FIG. 6 and the semiconductor package 1000 of FIG. 1 described above.

An optical fiber unit 300a of the semiconductor package 1000a may include the frame 310, the optical fiber 320, and an alignment pin 330a.

The alignment pin 330a of the optical fiber unit 300a may extend from one side surface of the frame 310 into the alignment hole 100_H of the package substrate 100. For example, at least a portion of the alignment pin 330a may be located inside the alignment hole 100_H of the package substrate 100. A shape of the alignment hole 100_H may correspond to a shape of the alignment pin 330a.

In some embodiments, the alignment pin 330a may include a plurality of regions in which an area T_330a of a cross-section (hereinafter, referred to as a vertical cross-section or a cross-section viewed from an axial direction) of the alignment pin 330a taken in a direction perpendicular to an extension direction of the alignment pin 330a varies. In some embodiments, the alignment pin 330a may include a region in which the area T_330a of the vertical cross-section is constant and a region in which the area T_330a gradually decreases. The end of the alignment pin 330a located inside the alignment hole 100_H may be located in the region in which the area T_330a of the vertical cross-section gradually decreases. For example, the alignment pin 330a may have one end that is pointed.

In some embodiments, the area T_330a of the vertical cross-section of the alignment pin 330a may gradually decrease away from the frame 310. For example, at least a portion of the alignment pin 330a may have a square pyramid shape or a cone shape.

In some embodiments, when the area T_330a of the vertical cross-section of the alignment pin 330a decreases, a length, or a thickness, of the alignment pin 330a in the vertical direction (the Z direction) may decrease. Accordingly, when the alignment pin 330a of the optical fiber unit 300a is pre-aligned with the package substrate 100, an error of the alignment pin 330a in the vertical direction (the Z direction) may be relatively small.

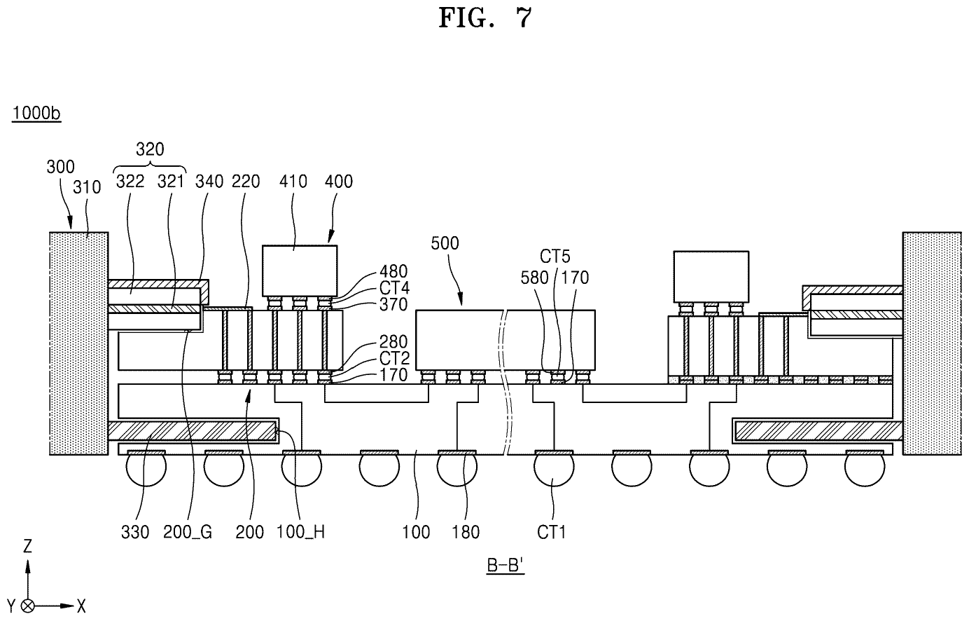

FIG. 7 is a cross-sectional view schematically illustrating a semiconductor package 1000b, taken along line B-B′ of FIG. 2, according to an embodiment.

Most of the components constituting the semiconductor package 1000b described below and materials forming the components are substantially the same as or similar to those described above with reference to FIG. 1. Therefore, for convenience of explanation, the description focuses on differences between the semiconductor package 1000b of FIG. 7 and the semiconductor package 1000 of FIG. 1 described above.

The PIC chip 200 of the semiconductor package 1000b may be disposed on the package substrate 100. The PIC chip 200 may be electrically connected to the package substrate 100. The PIC chip 200 may be apart from the semiconductor chip 500 in the horizontal direction.

The PIC chip 200 may include the lower pad 280 located on the lower surface, that is, the inactive surface, of the first substrate (210 in FIG. 4). The lower pad 280 of the PIC chip 200 may be electrically connected to the upper pad 170 of the package substrate 100 through the connection terminal CT2.

In some embodiments, the vertical level (200_VL in FIG. 4) of the lower surface of the PIC chip 200 may be substantially the same as the vertical level (500_VL in FIG. 4) of the lower surface of the semiconductor chip 500. The connection terminals CT2 may be located between the lower pads 280 of the PIC chip 200 and the upper pads 170 of the package substrate 100, and the connection terminals CT5 may be located between the lower pads 580 of the semiconductor chip 500 and the upper pads 170 of the package substrate 100. Accordingly, a distance between the PIC chip 200 and the package substrate 100 in the vertical direction (the Z direction) may be equal to a distance between the semiconductor chip 500 and the package substrate 100 in the vertical direction (the Z direction).

In some embodiments, the semiconductor package 1000b may further include a first underfill layer surrounding the lower pads 280 of the PIC chip 200, the upper pads 170 of the package substrate 100, and the connection terminals CT2, and a second underfill layer surrounding the lower pads 280 of the semiconductor chip 500, the upper pads 170 of the package substrate 100, and the connection terminals CT5.

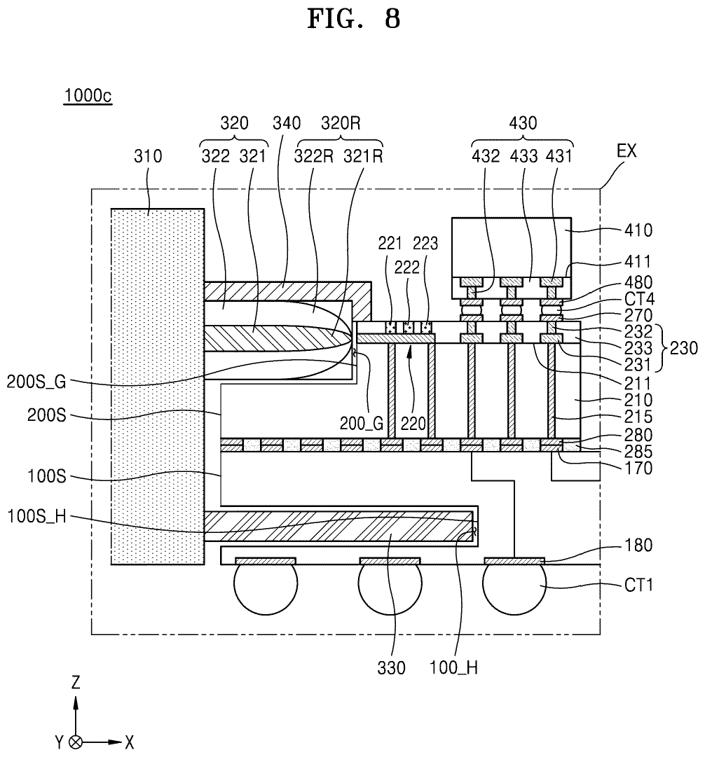

FIG. 8 is a cross-sectional view schematically illustrating an enlarged portion “EX” of FIG. 4 of a semiconductor package 1000c, according to an embodiment.

Most of the components constituting the semiconductor package 1000c described below and materials forming the components are substantially the same as or similar to those described above with reference to FIG. 1. Therefore, for convenience of explanation, the description focuses on differences between the semiconductor package 1000c of FIG. 8 and the semiconductor package 1000 of FIG. 1 described above.

The semiconductor package 1000c may include at least one optical fiber 320. In some embodiments, at least one optical fiber 320 may emit optical signals having different wavelengths. In some embodiments, each optical fiber of the at least one optical fiber 320 may emit multi-wavelength optical signals having multiple peak wavelengths.

The optical fiber 320 may have a lens region 320R located at one end. The lens region 320R may be a region in which an area of a cross-section (hereinafter referred to as vertical cross-section or a cross-section viewed from an axial direction) of the optical fiber 320 perpendicular to a direction in which the optical fiber 320 extends decreases. In some embodiments, a core layer 321R located in the lens region 320R may have an area of a cross-section decreasing toward the end of the optical fiber 320. An area of a vertical cross-section of the clad layer 322R located in the lens region 320R may decrease toward the end of the optical fiber 320.

In some embodiments, the vertical level (321_VL in FIG. 5) of the core layer 321R located in the lens region 320R of the optical fiber 320 may be substantially equal to the vertical level (220_VL in FIG. 5) of the edge coupler (225 in FIG. 5) of the photo-electron conversion unit 220 of the PIC chip 200. In detail, the center of the core layer 321R located in the lens region 320R of the optical fiber 320 may be aligned with the center of the edge coupler of the photo-electron conversion unit 220 of the PIC chip 200 in the horizontal direction.

The lens region 320R of the optical fiber 320 may improve the positional accuracy of the optical signal emitted from the optical fiber 320. For example, the area of the end of the optical fiber 320 emitted from the optical fiber 320 may decrease by the lens region 320R, so that an emission location of the optical signal may be relatively accurate. Accordingly, the accuracy of optical signal transmission of the semiconductor package 1000c may be improved.

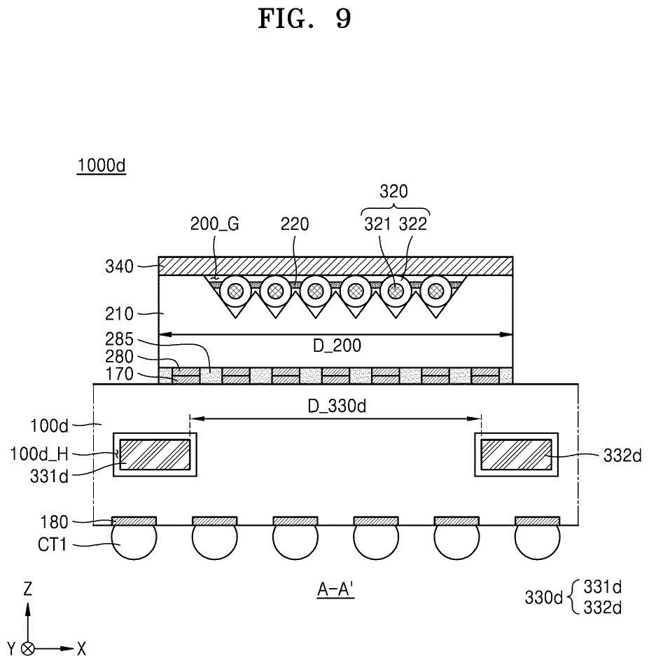

FIG. 9 is a cross-sectional view schematically illustrating a semiconductor package 1000d, taken along line A-A′ of FIG. 2, according to an embodiment.

Most of the components constituting the semiconductor package 1000d described below and the materials forming the components are substantially the same as or similar to those described above with reference to FIG. 1. Therefore, for convenience of explanation, the description focuses on differences between the semiconductor package 1000d of FIG. 9 and the semiconductor package 1000 of FIG. 1 described above.

A package substrate 100d of the semiconductor package 1000d may include a plurality of alignment holes 100d_H. The optical fiber unit 300 of the semiconductor package 1000d may include a plurality of alignment pins 330d. The alignment holes 100d_H may correspond to the alignment pins 330d, respectively. That is, one of the alignment pins 330d may be located inside each corresponding one of the alignment holes 100d_H.

Hereinafter, positions of the alignment pins 330d and the alignment holes 100d_H are described. However, for convenience of explanation, the description is given based on the alignment pins 330d.

The alignment pins 330d may include a first alignment pin 331d and a second alignment pin 332d. The first alignment pin 331d may be apart from the second alignment pin 332d in the horizontal direction. For example, the first alignment pin 331d may be apart from the second alignment pin 332d in the horizontal direction perpendicular to a direction in which the alignment pins 330d extend.

In some embodiments, a distance D_330d between the first alignment pin 331d and the second alignment pin 332d may be independent of a horizontal length D_200 of the PIC chip 200. That is, the distance D_330d between the first alignment pin 331d and the second alignment pin 332d may be equal to or different from the horizontal length D_200 of the PIC chip 200. In this specification, the horizontal length D_200 of the PIC chip 200 refers to a length of the PIC chip 200 in the horizontal direction perpendicular to the direction in which the alignment pins 330d extend.

In some embodiments, as shown in FIG. 9, the distance D_330d between the first alignment pin 331d and the second alignment pin 332d may be less than the horizontal length D_200 of the PIC chip 200. However, the inventive concept is not limited thereto, and the distance D_330d between the first alignment pin 331d and the second alignment pin 332d may be greater than the horizontal length D_200 of the PIC chip 200.

In FIG. 9, the optical fiber unit 300 including two alignment pins 330d is shown, but the number of alignment pins 330d is not limited thereto.

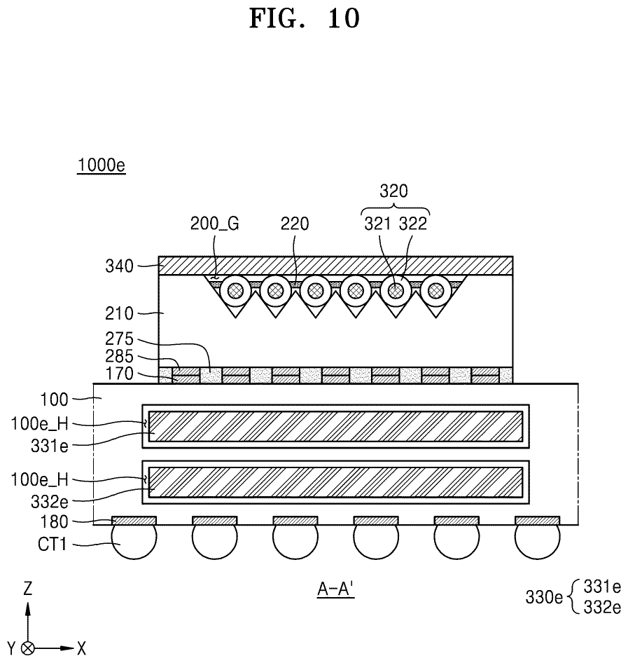

FIG. 10 is a cross-sectional view schematically illustrating a semiconductor package 1000e, taken along line A-A′ of FIG. 2, according to an embodiment.

Most of the components constituting the semiconductor package 1000e described below and materials forming the components are substantially the same as or similar to those described above with reference to FIG. 1. Therefore, for convenience of explanation, the description focuses on differences between the semiconductor package 1000e of FIG. 10 and the semiconductor package 1000 of FIG. 1 described above.

The package substrate 100e of the semiconductor package 1000e may include a plurality of alignment holes 100e_H. The optical fiber unit 300 of the semiconductor package 1000e may include a plurality of alignment pins 330e. The alignment holes 100e_H may correspond to the alignment pins 330e, respectively. That is, one of the alignment pins 330e may be located inside each of the alignment holes 100e_H.

Hereinafter, positions of the alignment pins 330e and the alignment holes 100e_H are described. However, for convenience of explanation, the description is given based on the alignment pins 330e.

The alignment pins 330e may include a first alignment pin 331e and a second alignment pin 332e. The first alignment pin 331e may be apart from the second alignment pin 332e in the vertical direction (the Z direction). For example, the first alignment pin 331e may overlap the second alignment pin 332e in the vertical direction (the Z direction).

In FIG. 10, although the first alignment pin 331e is shown to completely overlap the second alignment pin 332e in the vertical direction (the Z direction), the inventive concept is not limited thereto, and the first alignment pin 331e may only partially overlap the second alignment pin 332e in the vertical direction (the Z direction).

The first alignment pin 331e may be apart from the second alignment pin 332e in the vertical direction (the Z direction), so that, in the process of pre-aligning the optical fiber unit 300 and the package substrate 100, an alignment error between the optical fiber 320 and the photo-electron conversion unit 220 in the vertical direction (the Z direction) may be relatively small.

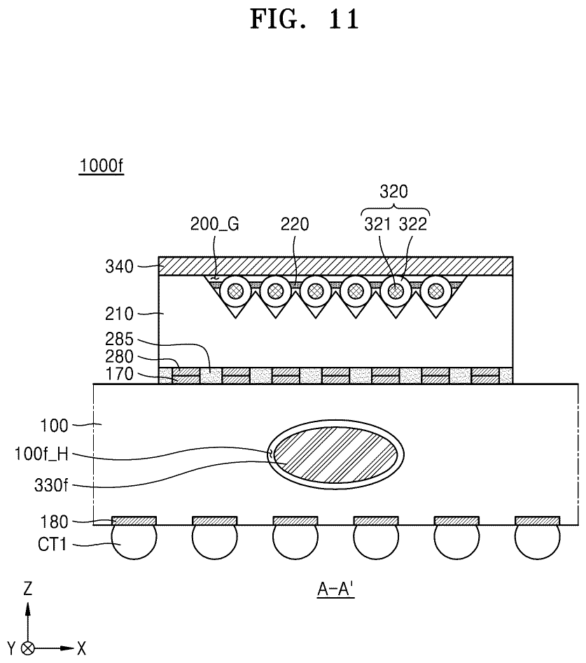

FIG. 11 is a cross-sectional view schematically illustrating a semiconductor package 1000f, taken along line A-A′ of FIG. 2, according to an embodiment.

Most of the components constituting the semiconductor package 1000f described below and materials forming the components are substantially the same as or similar to those described above with reference to FIG. 1. Therefore, for convenience of explanation, the description focuses on differences between the semiconductor package 1000f of FIG. 11 and the semiconductor package 1000 of FIG. 1 described above.

Referring to FIG. 11 together with FIG. 4, an alignment pin 330f of the optical fiber unit 300 of the semiconductor package 1000f may be located inside an alignment hole 100f_H of the package substrate 100f. The alignment pin 330f may extend from the frame 310 of the optical fiber unit 300 toward the alignment hole 100f_H.

As shown in FIG. 4, a cross-section of the alignment pin 330 taken in a direction perpendicular to an extension direction of the alignment pin 330 may have a square shape. For example, the alignment pin 330 may have a square pillar shape. However, the cross-section of the alignment pin 330 taken in the direction perpendicular to the extension direction of the alignment pin 330 is not limited thereto and may have a polygonal shape, such as a triangular shape or a pentagonal shape.

As shown in FIG. 11, the cross-section of the alignment pin 330f taken in the direction perpendicular to the extension direction of the alignment pin 330f may have a circular or elliptical or oval shape. For example, the alignment pin 330f may have a circular pillar shape.

A shape of the alignment hole 100f_H may correspond to the shape of the alignment pin 330f. For example, when the alignment pin 330f is has a square pillar shape, the alignment hole 100f_H may have a square pillar shape. When the alignment pin 330f has a circular pillar shape, the alignment hole 100f_H may have a circular pillar shape. The different shapes described above (e.g., polygonal shape, such as rectangular, square, triangular, pentagonal, or circular or elliptical or oval) may apply to any of the embodiments depicted in FIGS. 1-10.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate including an alignment hole extending inwardly from a side surface of the package substrate;
a photonic integrated circuit chip disposed on the package substrate, the photonic integrated circuit chip including a groove extending inwardly from a side surface of the photonic integrated circuit chip, and a photo-electron conversion unit including an edge coupler; and
an optical fiber connector including a frame, an optical fiber mounted in the groove of the photonic integrated circuit chip and passing through the frame, and an alignment pin extending from the frame to an inside of the alignment hole,
wherein the edge coupler is located at one end of the photo-electron conversion unit.

2. The semiconductor package of claim 1, wherein the edge coupler of the photo-electron conversion unit of the photonic integrated circuit chip has a constant thickness and faces the optical fiber.

3. The semiconductor package of claim 1, wherein:
the optical fiber includes a core layer and a clad layer covering the core layer, and a vertical level of a vertical center of the core layer of the optical fiber in the groove is equal to a vertical level of a vertical center of the edge coupler.

4. The semiconductor package of claim 1, wherein a side surface of the frame of the optical fiber connector faces a side surface of the photonic integrated circuit chip in which the groove is located and faces a side surface of the package substrate in which the alignment hole is located.

5. The semiconductor package of claim 4, wherein a sidewall of the groove facing the side surface of the frame and farthest from the side surface of the frame of the optical fiber connector is closer to the frame of the optical fiber connector than a sidewall of the alignment hole facing the side surface of the frame and farthest from the frame of the optical fiber connector.

6. The semiconductor package of claim 1, wherein:
the optical fiber and the alignment pin extend from a first side surface of the frame, and
a horizontal length in a first horizontal direction from the first side surface of the frame to an end of the optical fiber located in the groove is less than a horizontal length in the first horizontal direction from the first side surface of the frame to the end of the alignment pin located in the alignment hole.

7. The semiconductor package of claim 1, wherein the alignment hole of the package substrate is apart from upper and lower surfaces of the package substrate.

8. The semiconductor package of claim 1, wherein the alignment pin includes a plurality of regions having different areas when viewed from a cross-section perpendicular to a direction in which the alignment pin extends.

9. The semiconductor package of claim 1, wherein:
the photonic integrated circuit chip includes a plurality of through-vias.

10. A semiconductor package comprising:
a package substrate including at least a first alignment hole extending inwardly from a side surface of the package substrate;
a photonic integrated circuit chip disposed on the package substrate, the photonic integrated circuit chip including a groove extending inwardly from a side surface of the photonic integrated circuit chip and a photo-electron converter including a plurality of terminal end couplers;
a semiconductor chip disposed on the package substrate; and
an optical fiber connector including a frame, a plurality of optical fibers penetrating through the frame, and at least a first alignment pin extending from the frame to an inside of the first alignment hole,
wherein the plurality of terminal end couplers are located at a first end of the photo-electron converter.

11. The semiconductor package of claim 10, wherein each of the plurality of optical fibers of the optical fiber connector is configured to input/output an optical signal having multiple wavelengths from/to one of the plurality of terminal end couplers of the photonic integrated circuit chip.

12. The semiconductor package of claim 11, wherein the plurality of optical fibers of the optical fiber connector are configured to input/output optical signals having different wavelengths from/to the photonic integrated circuit chip.

13. The semiconductor package of claim 10, further comprising:
a second alignment pin of the optical fiber connector,
wherein the first alignment pin is apart from the second alignment pin are apart in a horizontal direction.

14. The semiconductor package of claim 13, wherein a distance between the first alignment pin and the second alignment pin is greater than a horizontal width of the photonic integrated circuit chip.

15. The semiconductor package of claim 10, further comprising:
a second alignment pin of the optical fiber connector,
wherein the first alignment pin overlaps the second alignment pin in a vertical direction.

16. A semiconductor package comprising:
a package substrate including at least a first alignment hole extending inwardly from a side surface of the package substrate;
a photonic integrated circuit chip disposed on the package substrate, the photonic integrated circuit chip including a groove extending inwardly from a side surface of the photonic integrated circuit chip and a photo-electron converter including a plurality of terminal end couplers;
a semiconductor chip disposed on the package substrate;
an electronic integrated circuit chip disposed on an upper surface of the photonic integrated circuit chip; and
an optical fiber connector including a frame, a plurality of optical fibers penetrating through the frame and mounted in the groove, and at least a first alignment pin extending from the frame to an inside of the first alignment hole,
wherein the plurality of terminal end couplers are located at one end of the photo-electron converter, and
wherein the first alignment hole of the package substrate is apart from upper and lower surfaces of the package substrate.

17. The semiconductor package of claim 16, wherein:
a side surface of the photonic integrated circuit chip in which a groove is located faces the same direction as a side surface of the package substrate in which the first alignment hole is located, and
an length of the groove in the extension direction of the groove is shorter than a length of the first alignment hole in the extension direction of the first alignment hole.

18. The semiconductor package of claim 16, wherein the first alignment pin of the optical fiber connector includes a region in which a thickness decreases along an axial direction of the first alignment pin.

19. The semiconductor package of claim 16, further comprising:
a second alignment pin of the optical fiber connector,
wherein the first alignment pin is apart from the second alignment pin in at least one of a vertical direction and a horizontal direction.
